(19) United States
(12) Patent Application Publication
(10) Pub. No.: US 2025/0267946 A1
(43) Pub. Date: Aug. 21, 2025

(54) SEMICONDUCTOR STRUCTURE AND METHOD OF MANUFACTURING THE SAME

(71) Applicant: NANYA TECHNOLOGY CORPORATION, New Taipei city (TW)

(72) Inventor: Yuan Sheng TSAI, New Taipei City (TW)

(21) Appl. No.: 18/443,683

(22) Filed: Feb. 16, 2024

(51) Int. Cl. H01L 27/01

(52) U.S. Cl. CPC H10D 86/85; H10D 1/042; H10D 1/716

(57) ABSTRACT

Embodiments of this disclosure provide a semiconductor structure, including a substrate, a lower electrode layer on the substrate, a first dielectric layer on the lower electrode layer and capacitor structures in the first dielectric layer and the second dielectric layer and each of the plurality of capacitor structures includes a sealing layer in an upper portion of each of the capacitor structures, a first conductive layer surrounding a sidewall and a bottom surface of the sealing layer, a top capacitor plate surrounding a sidewall and a bottom surface of the first conductive layer, an oxide layer surrounding a sidewall and a bottom surface of the top capacitor plate and a bottom capacitor plate on the lower electrode layer and surrounding a sidewall and a bottom surface of the oxide layer. In addition, a method of manufacturing a semiconductor structure is also disclosed in this disclosure.

### BACKGROUND

### Field of Invention

The present disclosure relates to a semiconductor structure and a method of manufacturing the same. More particularly, the present disclosure relates to a semiconductor structure and a method of manufacturing the same containing a capacitor structure without seam.

### Description of Related Art

As electronic devices become lighter and thinner, semiconductor devices, such as dynamic random access memory (DRAM) become more highly integrated. Further, the performance of the DRAM is improved via shortening the pitch between the semiconductor structures in the DRAM. In addition to increasing the difficulty of the manufacturing process, the components in the semiconductor structures are also prone to leakage resulting from too close distances because of shrinking the size of the semiconductor structure.

As a result, in the semiconductor manufacturing process, how to reduce the leakage to improve the process yield of the semiconductor structure has become an important issue.

### SUMMARY

Embodiments of this disclosure provide a method of manufacturing a semiconductor structure, including the following steps. A substrate and a lower electrode layer disposed on the substrate are provided. A first dielectric layer over the lower electrode layer is deposited. A second dielectric layer on the first dielectric layer is deposited. A plurality of first openings in the first dielectric layer and the second dielectric layer are formed, and each of the plurality of the first openings exposes a surface of a portion of the lower electrode layer. A bottom capacitor plate, an oxide layer and a top capacitor plate are formed in each of the plurality of first openings in sequence. A first conductive layer is formed on the top capacitor plate, and a seam exists in a top portion of the first conductive layer. A sealing layer is deposited in the seam, and on an inner sidewall of the oxide layer and a top surface of the second dielectric layer. The sealing layer is oxidized on the inner sidewall of the oxide layer and the top surface of the second dielectric layer to form an oxidized sealing layer. The oxidized sealing layer is removed on the inner sidewall of the oxide layer and the top surface of the second dielectric layer to form a plurality of second openings.

In some embodiments, an upper portion of an inner surface of the second dielectric layer in each of the first openings is exposed after forming the bottom capacitor plate.

In some embodiments, after forming the bottom capacitor plate, the oxide layer is conformally deposited on the bottom capacitor plate and on the upper portion of the inner surface of the second dielectric layer in each of the first openings.

In some embodiments, after forming the oxide layer, the top capacitor plate is formed on the oxide layer in each of the first openings, and an upper inner surface of the oxide layer is exposed.

In some embodiments, an upper portion of the first conductive layer is wider than a lower portion of the first conductive layer.

In some embodiments, the method further includes the following steps. A first film layer is deposited in each of the plurality of second openings. A second film layer is deposited on the first film layer. A second conductive layer is formed on the first film layer in each of the second openings.

In some embodiments, each of the second openings is a bowl shape.

In some embodiments, the first conductive layer includes SiGe.

In some embodiments, the sealing layer is oxidized by an asher oxidation process.

In some embodiments, the oxidized sealing layer is removed by a dilute HF clean process.

Embodiments of this disclosure also provides a semiconductor structure, including a substrate, a lower electrode layer on the substrate, a first dielectric layer on the lower electrode layer and a plurality of capacitor structures in the first dielectric layer and the second dielectric layer. Also, each of the plurality of capacitor structures includes a sealing layer in an upper portion of each of the plurality of capacitor structures, a first conductive layer over the lower electrode layer and surrounding a sidewall and a bottom surface of the sealing layer, a top capacitor plate over the lower electrode layer and surrounding a sidewall and a bottom surface of the first conductive layer, an oxide layer over the lower electrode layer and surrounding a sidewall and a bottom surface of the top capacitor plate and a bottom capacitor plate on the lower electrode layer and surrounding a sidewall and a bottom surface of the oxide layer.

In some embodiments, the semiconductor structure further includes a second conductive layer over the first conductive layer and the top capacitor plate, a second film layer surrounding a sidewall and a bottom surface of the second conductive layer and a first film layer surrounding a sidewall and a bottom surface of the second film layer.

In some embodiments, a bottom surface of the bottom capacitor plate contacts a top surface of the lower electrode layer.

In some embodiments, an upper portion of the first conductive layer has an upper width, a lower portion of the first conductive layer has a lower width, and the upper width is greater than the lower width.

In some embodiments, the sealing layer is an U-shape in a cross-section view.

In some embodiments, the oxide layer on an upper portion of an inner sidewall of the second dielectric layer surrounds a sidewall of the first film layer.

In some embodiments, a top surface of the second conductive layer and a top surface of the second dielectric layer are coplanar.

In some embodiments, the top capacitor plate comprises TiN.

In some embodiments, the sealing layer comprises TiN.

In some embodiments, the second conductive layer comprises indium tin oxides.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. The disclosure can be more fully understood by reading the following detailed description of the embodiment, with reference made to the accompanying drawings as follows.

FIGS. 1-2 are views of a method of manufacturing a semiconductor structure in some stages according to some embodiments of this disclosure,

FIGS. 3-6 are views of a method of manufacturing a semiconductor structure in sealing stages according to some embodiments of this disclosure, and

FIGS. 7-8 are views of a method of manufacturing a semiconductor structure in some stages according to some embodiments of this disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “on,” “over,” “under,” “between” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The words “comprise”, “include”, “have”, “contain” and the like used in the present disclosure are open terms, meaning including but not limited to.

In related art, an upper portion of a capacitor structure (also called container) is embedded with Ti, TiN and indium tin oxides (ITO) through a Damascus process. Since a conductive layer (such as SiGe) inside the capacitor structure is deposited through a furnace deposition process, leading to a seam (such as polysilicon-seam) problem due to a step coverage limitation of deposition, a void is generated at the seam after forming Ti, TiN and indium tin oxides (ITO) on the conductive layer. Furthermore, a resistance value is affected by the existence of the seam and the void at a contact surface between TiN and the conductive layer. Additionally, the long-term transportation also causes inevitable oxidation of the conductive layer and a capacitor plate surrounding the conductive layer. Thus, embodiments of this disclosure provide a semiconductor structure and a method of manufacturing a semiconductor structure to solve the problem of affecting the resistance value caused by the seam.

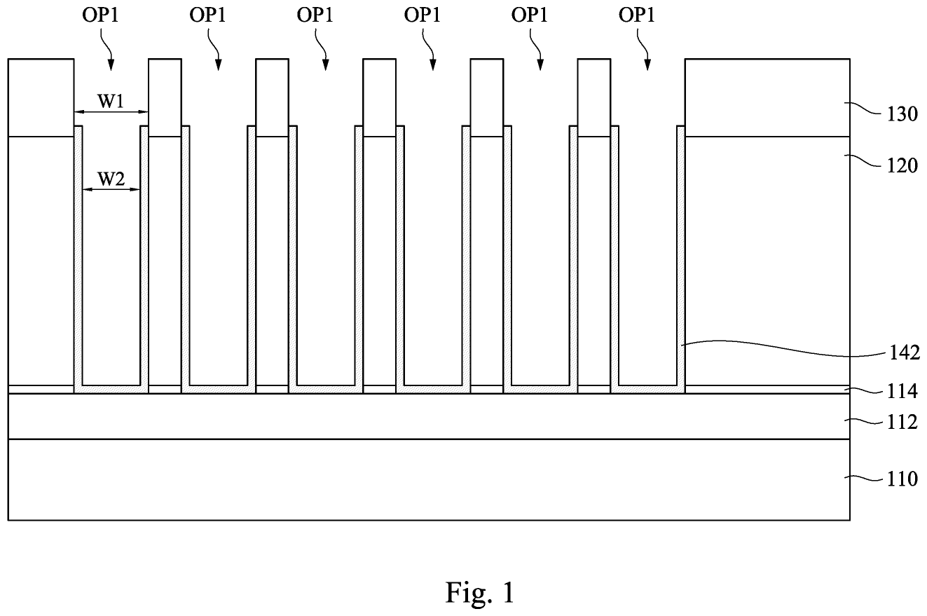

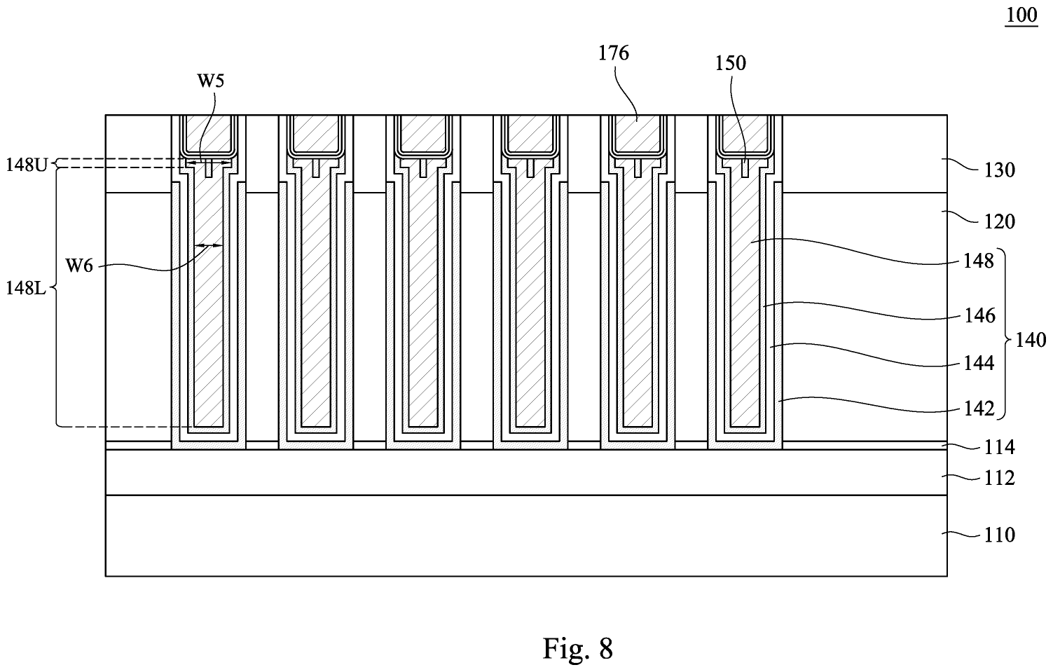

It should be noted that when the following figures, such as FIGS. 1 to 8, are illustrated and described as a series of operations or steps, the description order of these operations or steps should not be limited. For example, some operations or steps may be undertaken in a different order than in the present disclosure, or some operations or steps may occur currently, or some operations may not be used, and/or some operations or steps may be repeated. Moreover, the actual operations or steps of process stages may require additional operations or steps before, during or after forming the semiconductor structure (for example, a semiconductor structure 100 in FIG. 8) to completely form the semiconductor structure 100. Therefore, the present disclosure may briefly illustrate some of these additional operations or steps. Further, unless otherwise stated, the same explanations discussed for the following figures, such as FIGS. 1 to 8, apply directly to the other figures.

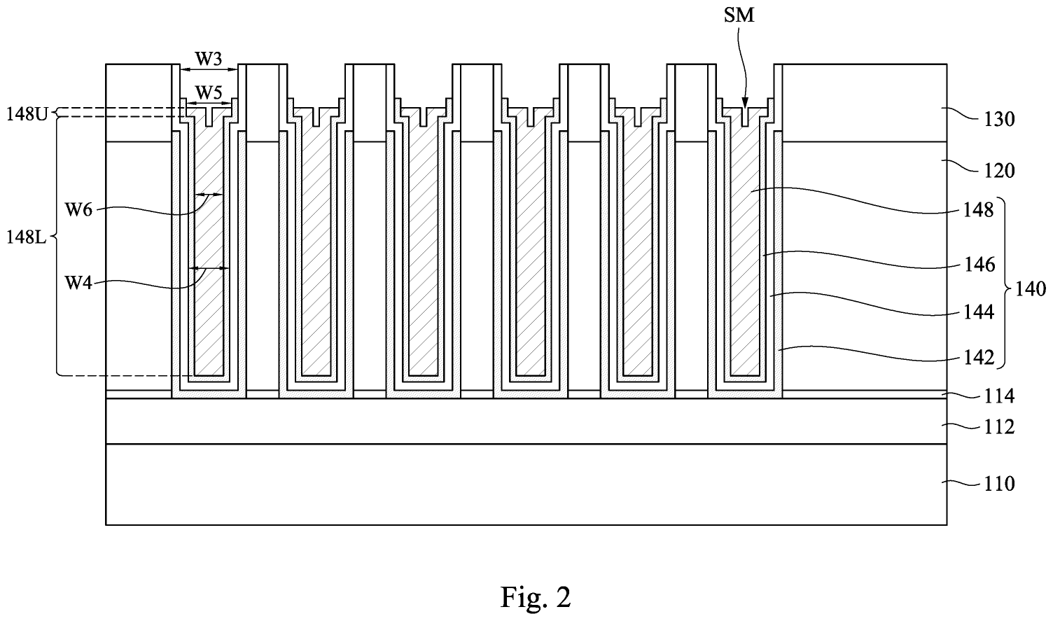

Please refer to FIGS. 1-2. FIGS. 1-2 are views of a method of manufacturing a semiconductor structure at some stages according to some embodiments of this disclosure. In FIG. 1, a substrate 110 and a lower electrode layer 112 disposed on the substrate 110 are provided. Additionally, an active layer (not shown) including a plurality of active structures, such as active areas, word line structures, contact plugs and like, is located between the substrate 110 and the lower electrode layer 112.

In some embodiments, the substrate 110 may include silicon, such as crystalline silicon, polycrystalline silicon, or amorphous silicon. The substrate 110 may include an elemental semiconductor, such as germanium. In some embodiments, the substrate 110 may include alloy semiconductors, such as silicon germanium, silicon germanium carbide, gallium indium phosphide, or other suitable materials. In some embodiments, the substrate 110 may include compound semiconductors, such as silicon carbide (SiC), gallium arsenide (GaAs), indium phosphide (InP), indium arsenide (InAs), or other suitable materials. Moreover, in some embodiments, the substrate 110 can optionally have a semiconductor-on-insulator (SOI) structure.

Next, an etch stop layer 114 is formed on the lower electrode layer 112. Subsequently, a first dielectric layer 120 is deposited on the etch stop layer 114. In some embodiments, the first dielectric layer 120 includes tetraethoxysilane (TEOS). In some embodiments, the first dielectric layer 120 is deposited by chemical vapor deposition (CVD), physical vapor deposition (PVD), atomic layer deposition (ALD) or other suitable deposition process. Further, a second dielectric layer 130 is deposited on the first dielectric layer 120. In some embodiments, the second dielectric layer 130 includes SiN. In some embodiments, the second dielectric layer 130 is deposited by CVD, PVD, ALD or other suitable deposition process.

Then, a plurality of first openings OP1 are formed in the first dielectric layer 120 and the second dielectric layer 130 until exposing surfaces of portions of the lower electrode layer 112. A bottom capacitor plate 142 is conformally deposited in a lower portion of each of the first openings OP1. Specifically, the bottom capacitor plate 142 is conformally deposited on each of the top surfaces of the portions of the lower electrode layer 112, an inner surface of the first dielectric layer 120 and a lower portion of an inner surface of the second dielectric layer 130 in the each of the first openings OP1. That is, an upper portion of the inner surface of the second dielectric layer 130 is not covered with the bottom capacitor plate 142 and exposed. In some embodiment, the bottom capacitor plate 142 includes TiN. Moreover, a first width W1 is measured from an inner side of each of the first openings OP1 to the other inner side of each of the first openings OPI at a section cross the seam SM (such as in FIG. 2 described later), a second width W2 is measured from an inner side of the bottom capacitor plate 142 to the other inner side of the bottom capacitor plate 142 at the section cross the seam SM (such as in FIG. 2 described later), and the first width W1 is greater than the second width W2.

In FIG. 2, a plurality of capacitor structures 140 are formed over the substrate 110. Specifically, an oxide layer 144 is conformally deposited on the bottom capacitor plate 142 and on the upper portion of the inner surface of the second dielectric layer 130 in each of the first openings OP1. Moreover, a third width W3 of the oxide layer 144 is measured from an upper inner side of the oxide layer 144 to the other lower inner side of the oxide layer 144 at the section cross the seam SM, a fourth width W4 of the oxide layer 144 is measured from a lower inner side of the oxide layer 144 to the other lower side of the oxide layer 144 at the section cross the seam SM, and the third width W3 is greater than the fourth W4. In some embodiments, the oxide layer includes ZrOₓ or other suitable oxide.

Next, a top capacitor plate 146 is formed on the oxide layer 144 in each of the first openings OP1, and an upper inner surface of the oxide layer 144 is not covered with the top capacitor plate 146 and exposed. Moreover, a fifth width W5 of the top capacitor plate 146 is measured from an upper inner side of the top capacitor plate 146 to the other upper inner side of the top capacitor plate 146 at the section cross the seam SM, a sixth width W6 of the top capacitor plate 146 is measured from a lower inner side of the top capacitor plate 146 to the other lower inner side of the top capacitor plate 146 at the section cross the seam SM, and the fifth width W5 is greater than the sixth width W6. In some embodiments, the top capacitor plate 146 includes TiN.

Further, a first conductive layer 148 is deposited on the top capacitor plate 146 in each of the first openings OP1, and a seam SM is formed in a top portion of the first conductive layer 148. That is, each of the capacitor structures 140 includes the bottom capacitor plate 142, the oxide layer 144, the top capacitor plate 146 and the first conductive layer 148. Also, a lower portion 148L of the first conductive layer 148 has the sixth width W6, and an upper portion 148U of the first conductive layer 148 has the fifth width W5. Furthermore, since the fifth width W5 is greater than the sixth width W6, the upper portion of the first conductive layer 148 is wider than the lower portion of the first conductive layer 148. In some embodiments, the first conductive layer 148 is deposited by CVD in a furnace, PVD, ALD or other suitable deposition process. In some embodiments, the first conductive layer 148 includes SiGe. In some embodiments, the top capacitor plate 146 is not completely filled with the first conductive layer 148. In other words, a top surface of the first conductive layer 148 and a top surface of the top capacitor plate 146 are not coplanar.

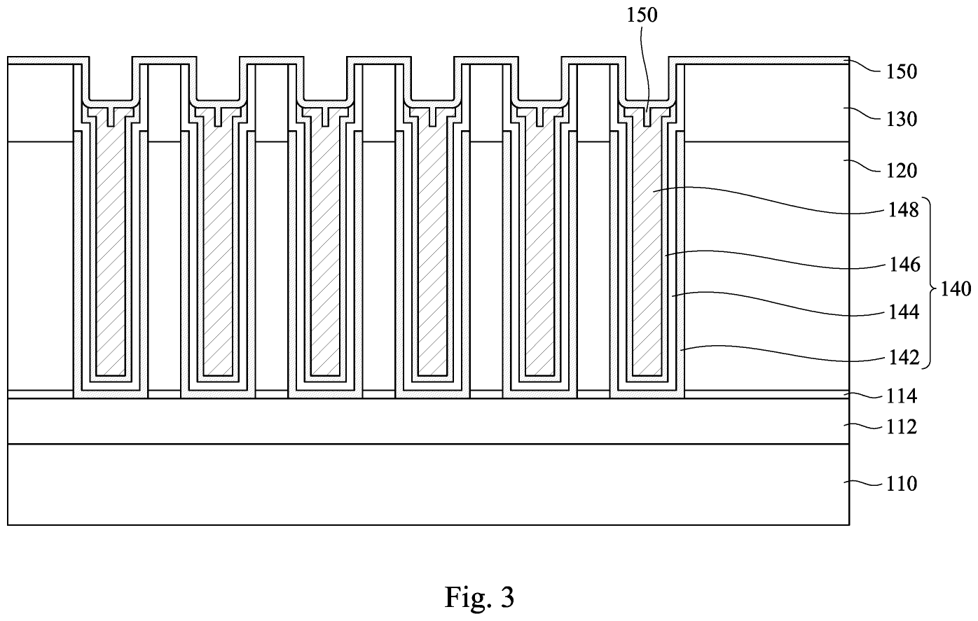

Next, please refer to FIGS. 3-6. FIGS. 3-6 are views of a method of manufacturing a semiconductor structure in sealing stages according to some embodiments of this disclosure. In FIG. 3, a sealing layer 150 is formed in the seam SM (such as in FIG. 2) in the top portion of the first conductive layer 148, and on an upper inner sidewall of the oxide layer 144 and a top surface of the second dielectric layer 130. In some embodiments, the sealing layer 150 is formed by CVD, PVD, ALD or other suitable deposition process. In some embodiments, the sealing layer 150 includes TiN.

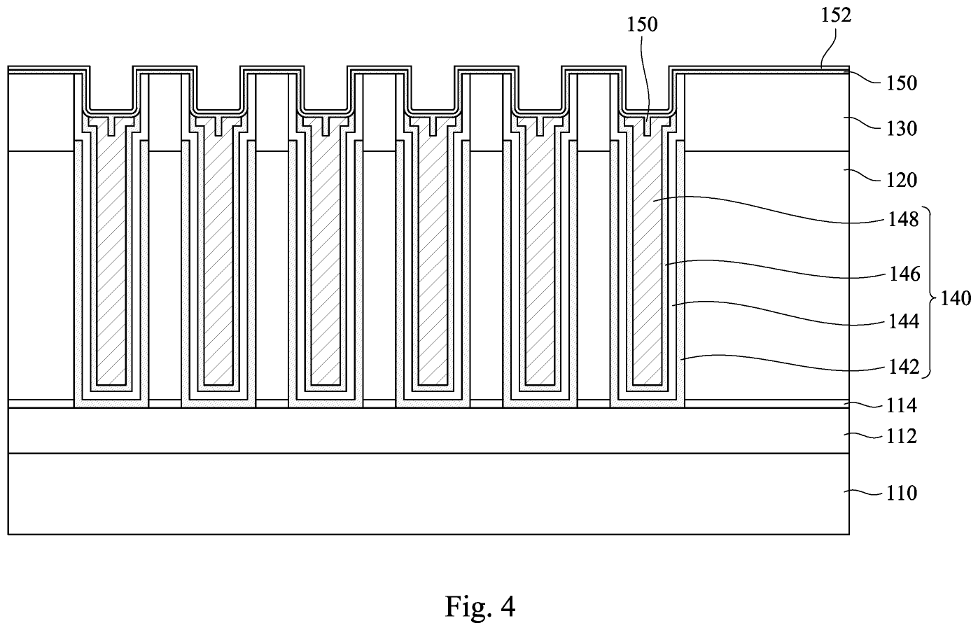

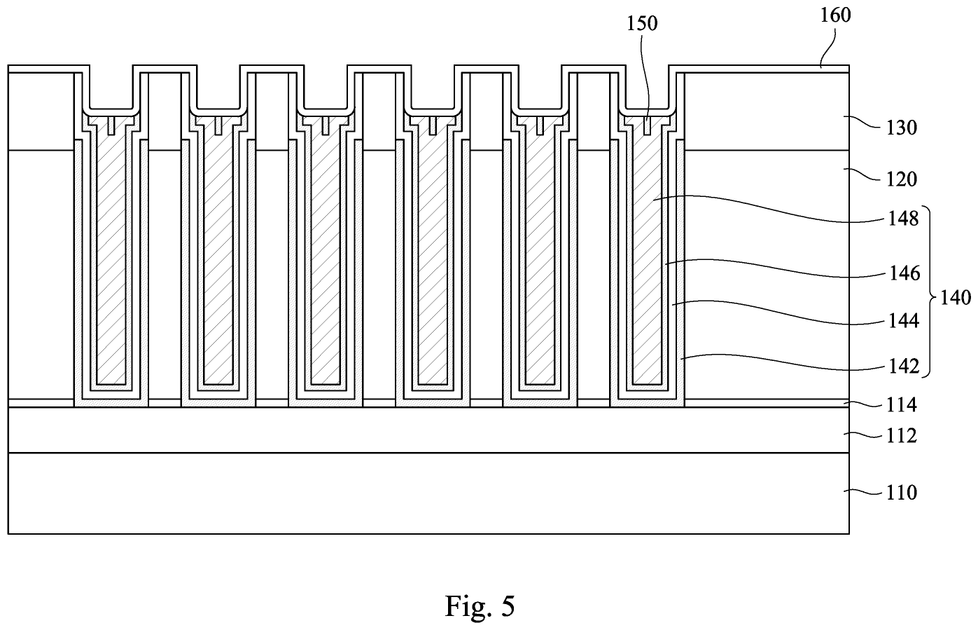

In FIG. 4, a surface of the sealing layer 150 is oxidized naturally to form a thin oxidized sealing layer 152 after the substrate 110 is transferred out of the fabrication. Next, in FIG. 5, the sealing layer 150 on a top surface of the sealing layer 150 in the seam SM (such as in FIG. 2), the top surface of the first conductive layer 148, the upper inner sidewall of the oxide layer 144 and the top surface of the second dielectric layer 130 is oxidized to form an oxidized sealing layer 160. In some embodiments, the oxidized sealing layer 160 is formed by an asher oxidation process.

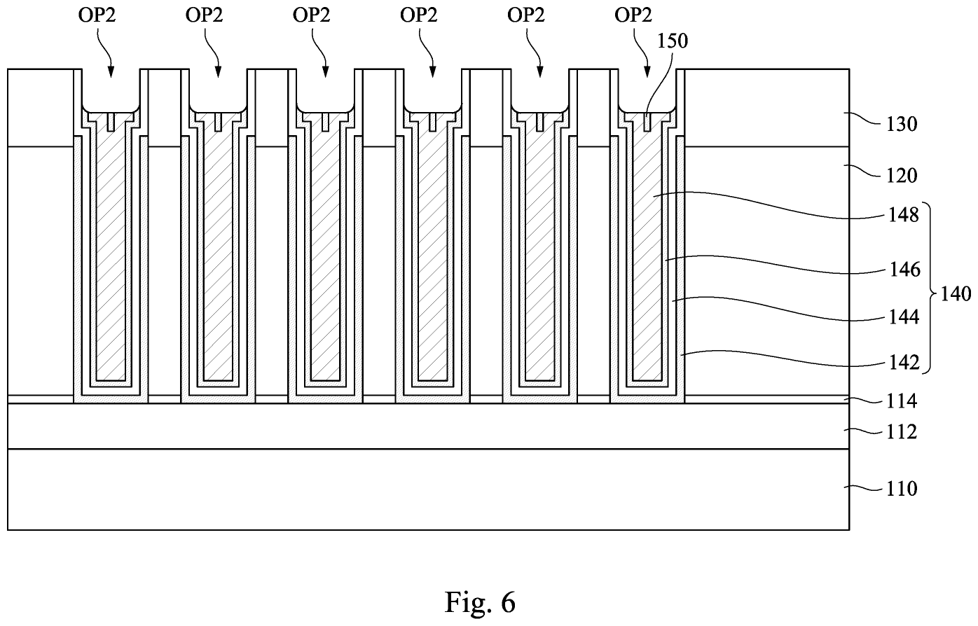

In FIG. 6, the oxidized sealing layer 160 (such as in FIG. 5) on the top surface of the sealing layer 150 in the seam SM (such as in FIG. 2), the top surface of the first conductive layer 148, the upper inner sidewall of the oxide layer 144 and the top surface of the second dielectric layer 130 is removed to form a plurality of second openings OP2. In some embodiments, the oxidized sealing layer 160 (such as in FIG. 5) is removed by a dilute HF (DHF) clean process. In some embodiments, each of the second openings OP2 is a bowl shape. In some embodiment, the sealing layer 150 in the seam SM (such as in FIG. 2) is an U-shape in a cross-section view. In this way, filling the sealing layer 150 in the seam SM (such as in FIG. 2) not only can solve the resistance problem of a capacitor structure 140 of a semiconductor structure 100 (such as in FIG. 8), but also prevent the top capacitor plate and/or the bottom capacitor plate from being oxidized due to exposing in air.

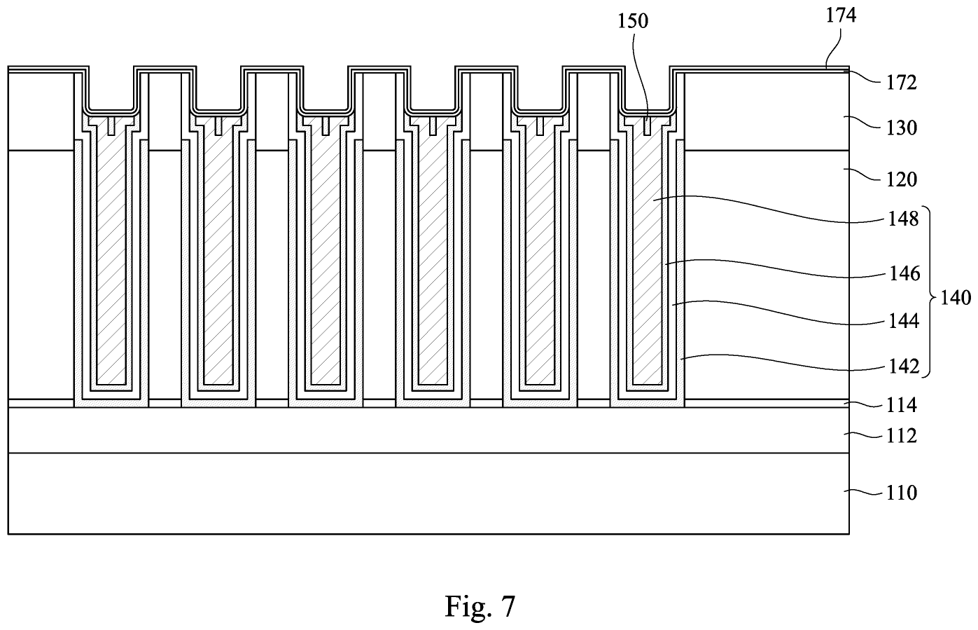

Further, please refer to FIGS. 7-8. FIGS. 7-8 are views of a method of manufacturing a semiconductor structure in some stages according to some embodiments of this disclosure. In FIG. 7, a first film layer 172 is conformally formed in each of the second openings OP2 and a top surface of the second dielectric layer 130. In some embodiments, since each of the second openings OP2 is the bowl shape, the first film layer 172 formed in each of the second openings OP2 is the bowl shape. In some embodiments, the first film layer 172 includes TiN. Subsequently, a second film layer 174 is conformally formed on the first film layer 172 in each of the second openings OP2 and the top surface of the second dielectric layer 130. Similarly, in some embodiments, the second film layer 174 conformally formed on the first film layer 172 is the bowl shape. In some embodiments, the second film layer 174 includes Ti.

In FIG. 8, a second conductive layer 176 is formed on the second film layer 174 in each of the second openings OP2. In some embodiments, a bottom surface of the second conductive layer 176 is the bowl shape. In some embodiments, the second conductive layer 176 includes ITO. In some embodiments, the first film layer 172, the second film layer 174 and the second conductive layer 176 are formed by a Damascus damascene process. Then, a planarization process is performed, so that a top surface of the second conductive layer 176 and the top surface of the second dielectric layer 130 are coplanar. Additionally, since an upper electrode layer is provided and formed over the second conductive layer 176, so as to make the upper electrode layer be electrically connected to the lower electrode layer 112 through a capacitor structure 140 and the second conductive layer 176 after some subsequent processes for manufacturing a capacitor structure 140, the upper electrode layer is not shown in figures and contents in this disclosure.

A semiconductor structure 100 is provided shown in FIG. 8. The semiconductor structure 100 includes a substrate 110, a lower electrode layer 112 on the substrate 110, a first dielectric layer 120 on the lower electrode layer 112, a second dielectric layer 130 on the first dielectric layer 120 and a plurality of capacitor structures 140 in the first dielectric layer 120 and the second dielectric layer 130. In some embodiments, an etch stop layer 114 is disposed on lower electrode layer 112 and surrounding a bottom portion of an outside surface of each of the capacitor structures 140.

Each of the capacitor structures 140 includes a sealing layer 150 in an upper portion of each of the capacitor structures 140, a first conductive layer 148 over the lower electrode layer 112 and surrounding a sidewall and a bottom surface of the sealing layer 150, a top capacitor plate 146 over the lower electrode layer 112 and surrounding a sidewall and a bottom surface of the first conductive layer 148, an oxide layer 144 over the lower electrode layer 112 and surrounding a sidewall and a bottom surface of the top capacitor plate 146 and a bottom capacitor plate 142 on the lower electrode layer 112 and surrounding a sidewall and a bottom surface of the oxide layer 144. In some embodiments, the sealing layer 150 is an U-shape in a cross-section view. In some embodiment, the sealing layer 150 includes TiN. In some embodiment, the top capacitor plate 146 includes TiN. In some embodiments, the oxide layer 144 includes ZrOₓ. In some embodiments, the bottom capacitor plate 142 includes TIN. In some embodiments, the first conductive layer 148 includes SiGe.

Specifically, an outside surface of the bottom capacitor plate 142 contacts a top surface of the lower electrode layer 112 and an inner surface of the first dielectric layer 120 and a lower portion of an inner surface of the second dielectric layer 130. Also, an upper portion of an outside surface of the oxide layer 144 contacts the upper portion of the inner surface of the second dielectric layer 130, and a lower portion of the outside surface of the oxide layer 144 contacts an inner surface of the bottom capacitor plate 142. An upper portion of an outside surface of the top capacitor plate 146 contacts a lower portion of the upper portion of an inner surface of the oxide layer 144, and a lower portion of the outside surface of the top capacitor plate 146 contacts the lower portion of the inner surface of the oxide layer 144.

Based on a shape formed the inner surface of the top capacitor plate 146, an upper portion of the first conductive layer 148 is wider than a lower portion of the first conductive layer 148. Moreover, the upper portion 148U of the first conductive layer 148 has an upper width (that is, the fifth width W5), the lower portion 148L of the first conductive layer 148 has a lower width (that is, the sixth width W6), and the upper width is greater than the lower width. In some embodiments, a top surface of the first conductive layer 148 and a top surface of the top capacitor plate 146 are not coplanar.

Further, the semiconductor structure 100 further includes a second conductive layer 176 over the first conductive layer 148 and the top capacitor plate 146, a second film layer 174 surrounding a sidewall and a bottom surface of the second conductive layer 176 and a first film layer 172 surrounding a sidewall and a bottom surface of the second film layer 174. Specifically, the first film layer 172 is conformally disposed on the first conductive layer 148 and the top capacitor plate 146. The oxide layer 144 on the upper portion of the inner sidewall of the second dielectric layer 130 surrounds a sidewall of the first film layer 172. Since a top surface formed collectively by the sealing layer 150, the first conductive layer 148 and the top capacitor plate 146 is a bowl shape, the first film layer 172 is the bowl shape. Also, since the second film layer 174 is conformally disposed on the first film layer 172, the second film layer 174 is the bowl shape. The second conductive layer 176 is disposed on the second film layer 174, and a bottom surface of the second conductive layer 176 is the bowl shape. In some embodiments, a top surface of the second conductive layer 176 and a top surface of the second dielectric layer 130 are coplanar. In some embodiments, the second conductive layer 176 comprises indium tin oxides.

As stated as above, through depositing the sealing layer in the seam generated in the first conductive layer and the top surface of the dielectric layer in the embodiments of this disclosure, a contact area of the first conductive layer/the sealing layer and the second conductive layer can be increased, and further an interface adhesion can be improved. In this way, the resistance of the capacitor structure can be decreased. Furthermore, since the top surface of the first conductive layer, the top surface of the top capacitor plate and the inner surface of the second dielectric layer are covered with the sealing layer, the top surface of the first conductive layer, the top surface of the top capacitor plate and the inner surface of the second dielectric layer are covered with the sealing layer can prevent from being oxidized. Thus, the resistance of the capacitor structure can be further improved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a semiconductor structure, comprising:
providing a substrate and a lower electrode layer disposed on the substrate;
depositing a first dielectric layer over the lower electrode layer;
depositing a second dielectric layer on the first dielectric layer;
forming a plurality of first openings in the first dielectric layer and the second dielectric layer, wherein each of the plurality of the first openings exposes a surface of a portion of the lower electrode layer;
forming a bottom capacitor plate, an oxide layer and a top capacitor plate in each of the plurality of first openings in sequence;
forming a first conductive layer on the top capacitor plate, wherein a seam exists in a top portion of the first conductive layer;
depositing a sealing layer in the seam, and on an inner sidewall of the oxide layer and a top surface of the second dielectric layer;
oxidizing the sealing layer on the inner sidewall of the oxide layer and the top surface of the second dielectric layer to form an oxidized sealing layer; and
removing the oxidized sealing layer on the inner sidewall of the oxide layer and the top surface of the second dielectric layer to form a plurality of second openings.

2. The method of claim 1, wherein an upper portion of an inner surface of the second dielectric layer in each of the first openings is exposed after forming the bottom capacitor plate.

3. The method of claim 2, wherein after forming the bottom capacitor plate, the oxide layer is conformally deposited on the bottom capacitor plate and on the upper portion of the inner surface of the second dielectric layer in each of the first openings.

4. The method of claim 1, wherein after forming the oxide layer, the top capacitor plate is formed on the oxide layer in each of the first openings, and an upper inner surface of the oxide layer is exposed.

5. The method of claim 1, wherein an upper portion of the first conductive layer is wider than a lower portion of the first conductive layer.

6. The method of claim 1, further comprising:
depositing a first film layer in each of the plurality of second openings;
depositing a second film layer on the first film layer; and
forming a second conductive layer on the first film layer in each of the second openings.

7. The method of claim 1, wherein each of the second openings is a bowl shape.

8. The method of claim 1, wherein the first conductive layer comprises SiGe.

9. The method of claim 1, wherein the sealing layer is oxidized by an asher oxidation process.

10. The method of claim 1, wherein the oxidized sealing layer is removed by a dilute HF clean process.

11. A semiconductor structure, comprising:
a substrate;
a lower electrode layer, disposed on the substrate;
a first dielectric layer, disposed on the lower electrode layer;
a second dielectric layer, disposed on the first dielectric layer; and
a plurality of capacitor structures, disposed in the first dielectric layer and the second dielectric layer, and each of the plurality of capacitor structures comprising:
a sealing layer, disposed in an upper portion of each of the plurality of capacitor structures;
a first conductive layer, disposed over the lower electrode layer and surrounding a sidewall and a bottom surface of the sealing layer;
a top capacitor plate, disposed over the lower electrode layer and surrounding a sidewall and a bottom surface of the first conductive layer;
an oxide layer, disposed over the lower electrode layer and surrounding a sidewall and a bottom surface of the top capacitor plate; and
a bottom capacitor plate, disposed on the lower electrode layer and surrounding a sidewall and a bottom surface of the oxide layer.

12. The semiconductor structure of claim 11, further comprising:
a second conductive layer, disposed over the first conductive layer and the top capacitor plate;
a second film layer, surrounding a sidewall and a bottom surface of the second conductive layer; and
a first film layer, surrounding a sidewall and a bottom surface of the second film layer.

13. The semiconductor structure of claim 11, wherein a bottom surface of the bottom capacitor plate contacts a top surface of the lower electrode layer.

14. The semiconductor structure of claim 11, wherein an upper portion of the first conductive layer has an upper width, a lower portion of the first conductive layer has a lower width, and the upper width is greater than the lower width.

15. The semiconductor structure of claim 11, wherein the sealing layer is an U-shape in a cross-section view.

16. The semiconductor structure of claim 12, wherein the oxide layer on an upper portion of an inner sidewall of the second dielectric layer surrounds a sidewall of the first film layer.

17. The semiconductor structure of claim 12, wherein a top surface of the second conductive layer and a top surface of the second dielectric layer are coplanar.

18. The semiconductor structure of claim 11, wherein the top capacitor plate comprises TiN.

19. The semiconductor structure of claim 11, wherein the scaling layer comprises TiN.

20. The semiconductor structure of claim 12, wherein the second conductive layer comprises indium tin oxides.
